(19) United States
(12) Patent Application Publication
(10) Pub. No.: US 2020/0040454 A1
(43) Pub. Date: Feb. 6, 2020

(54) METHOD TO INCREASE DEPOSITION RATE OF ALD PROCESS

(71) Applicant: Lam Research Corporation, Fremont, CA (US)

(72) Inventors: Dennis HAUSMANN, Lake Oswego, OR (US); Alexander R. FOX, Portland, OR (US); Colleen LAWLOR, Oneida, NY (US)

(21) Appl. No.: 16/056,301

(22) Filed: Aug. 6, 2018

(51) Int. Cl. C23C 16/455

(52) U.S. Cl. CPC C23C 16/45534; C23C 16/345; C23C 16/45553

(57) ABSTRACT

A method of increasing the deposition rate of an atomic layer deposition (ALD) process by co-flowing a volatile base with metal organic, a metal halide, or metal hybride precursor. The base does not react with the precursor with which it is flowed such that the base generates no measurable film on the substrate or particles in the processing chamber during the flow time. The addition of the base catalyst increases the rate of adsorption of the precursor with which it is flowed.

### BACKGROUND

The disclosure relates to a method for semiconductor processing. More specifically, the disclosure relates to a method for increasing the deposition rate of an atomic layer deposition (ALD) process.

ALD is a thin-film deposition method used in semiconductor processing and is considered as a deposition method that allows for deposition of very thin, conformal films at the atomic level. The thickness and composition of the deposited film can be precisely controlled with ALD deposition. Typically, in an ALD process, a semiconductor substrate is exposed to alternating precursors to grow a film on the surface of the substrate. Each ALD cycle includes pulsing of each of the precursors, where the pulses of the different precursors do not overlap, and the different precursors are never simultaneously present in the reactor. With each pulse, the precursor molecules react with the surface of the substrate to form the film on the surface, and the reaction stops once all of the reactive sites on the substrate surface are consumed.

However, ALD is known to be a very slow process, and the ALD's slow deposition rate is considered to be its major limitation. Deposition of silicon dioxide (SiO₂) using a conventional two precursor (e.g., silicon amide and O₂ plasma) ALD process typically results in a deposition rate of only about 1-2 Å per cycle, depending upon temperature. Thus, it would be desirable for an ALD process to have a faster rate of deposition.

### SUMMARY

According to an embodiment, a method is provided for increasing a deposition rate of an atomic layer deposition (ALD) process. A processing chamber is provided with a substrate in the chamber. A first precursor is flowed into the chamber. The first precursor includes a metal organic, a metal halide, or metal hybride, and the adsorption of the first precursor results in a growth of a film on the substrate. A base in a gaseous phase is co-flowed with the first precursor into the chamber to co-expose a surface of the substrate to the first precursor and the base. The base does not react with the first precursor such that the base does not generate any measurable film on the surface of the substrate and the base does not generate any measurable particles in the chamber. A second precursor is flowed into the chamber, and adsorption of the second precursor provides oxidation or nitridation of the film.

According to another embodiment, a method is provided for increasing a deposition rate of an atomic layer deposition (ALD) process. A processing chamber is provided with a substrate within the chamber. A first precursor is flowed into the chamber. The first precursor is a metal organic, a metal halide, or metal hybride, and adsorption of the first precursor results in a growth of a film on the substrate. A volatile base is co-flowed with the first precursor into the chamber to co-expose a surface of the substrate to the first precursor and the base. The base does not react with the first precursor such that the base does not generate any measurable film on the surface of the substrate and the base does not generate any measurable particles in the chamber. A volatile base or acid is co-flowed with a second precursor into the chamber, and adsorption of the second precursor provides oxidation or nitridation of the film.

According to yet another embodiment, a method is provided for increasing a deposition rate of a plasma-enhanced atomic layer deposition (ALD) process. A processing chamber is provided with a substrate within the chamber. A first precursor is flowed into the chamber. The first precursor is a metal organic, a metal halide, or metal hybride, and adsorption of the first precursor results in a growth of a film on the substrate. A base in a gaseous phase is co-flowed with the first precursor into the chamber to co-expose a surface of the substrate to the first precursor and the base. The base does not react with the first precursor such that the base does not generate any measurable film on the surface of the substrate and the base does not generate any measurable particles in the chamber. A second precursor, which is plasma ignited, is flowed into the chamber, and adsorption of the second precursor provides oxidation or nitridation of the film.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a flow chart of an ALD method with an increased deposition rate in accordance with an embodiment.

FIG. 2 is a flow chart of an ALD method with an increased deposition rate in accordance with another embodiment.

### DETAILED DESCRIPTION OF EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

The embodiments described herein relate generally to an atomic layer deposition (ALD) processes. In particular, the embodiments described herein relate to methods for increasing the deposition rate of an ALD process by co-flowing a volatile base with a precursor.

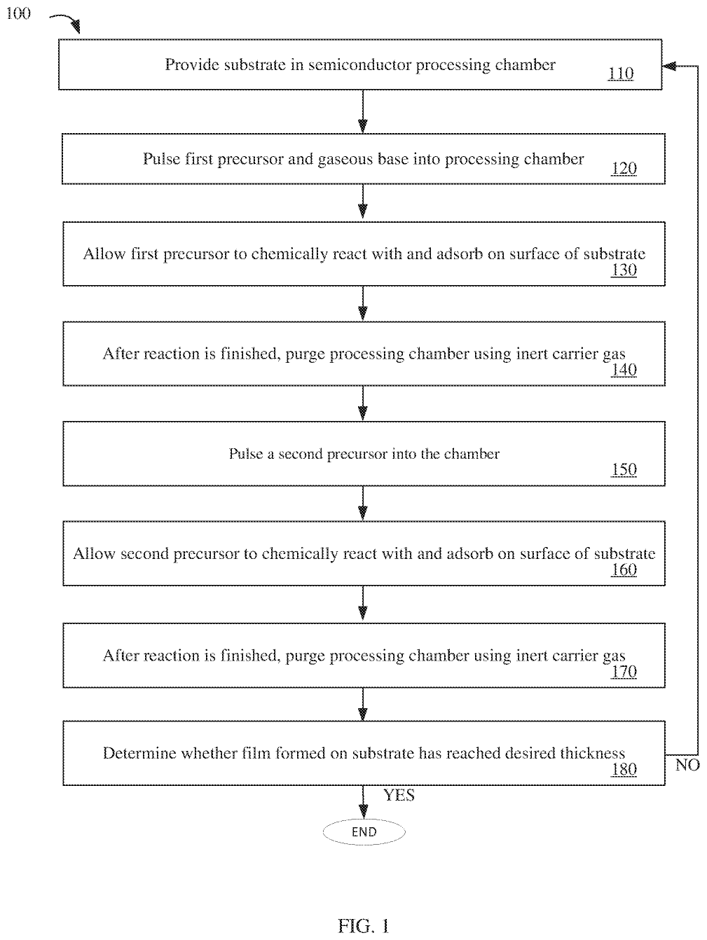

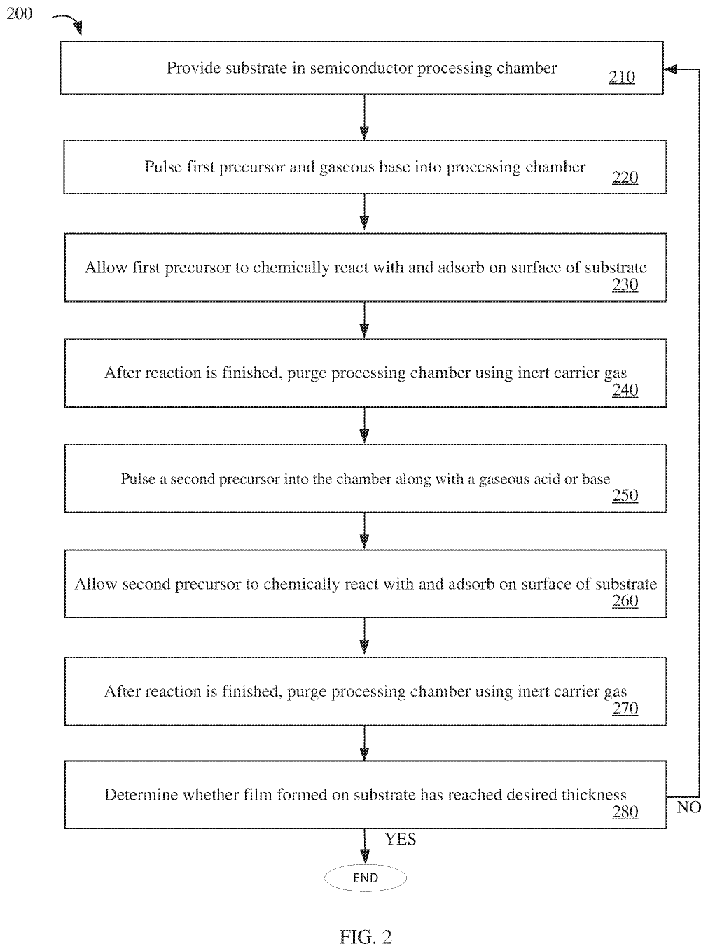

With reference to FIGS. 1 and 2, embodiments of an ALD process with an increased deposition rate are described. According to the embodiments described herein, the addition of a base catalyst is used to increase the deposition rate of an ALD process. As discussed in more detail below, metal amide or silicon amide precursors are used to increase the rate of precursor adsorption.

ALD is a useful thin film deposition process, as it allows for deposition of very thin, conformal films (even on substances with high-aspect ratios) with precise control of thickness and composition at the atomic level. Although ALD is a beneficial process in many ways, it is generally a very slow deposition process because of long cycle times due to the pulse and purge times and the layer-by-layer deposition nature of ALD, as discussed in more detail below.

An ALD cycle includes pulsing of a first precursor into a reaction chamber, time for the first precursor to adsorb on the surface of the substrate, purging of the chamber after all reactive sites on the substrate surface are consumed, pulsing of a second precursor into the reaction chamber, time for the second precursor to adsorb on the surface of the substrate, and purging of the chamber after all the reactive sites on the substrate surface are consumed. These cycles continue until the film on the substrate reaches the desired thickness.

Generally, conventional ALD processes “saturate” before a monolayer of film can be achieved on the substrate. That is, once the reactive sites on the surface of the substrate are consumed, the reaction between the precursor and the substrate surface stops. As noted above, after all of the reactive sites on the substrate are consumed, the chamber is typically purged of the remaining precursor and any by-products. The purge is typically carried out using inert carrier gas.

ALD is often used to deposit a metal oxide or silicon oxide layer. Thus, the first precursor is usually a metal oxide or silicon-based silane derivative. For silicon oxide (SiO₂) ALD, deposition rates of about 1-2 Å per cycle correspond to about 25-50% of a full monolayer (about 4 Å per cycle). Thus, it can take up to about 4 cycles to achieve a full monolayer.

In accordance with embodiments described herein, by co-flowing a volatile base in a gaseous phase with the precursor, the ALD deposition rate can be increased by about 40% (i.e., from about 1 Å per cycle to about 1.4 Å per cycle) compared with conventional ALD without co-flowing a base with the precursor. It will be understood that the base does not react with the precursor with which it is flowed such that the base generates no measurable film on the substrate or particles in the processing chamber during the flow time. In the embodiments described herein, the first precursor can be a metal organic, a metal halide, or metal hybride.

In some embodiments, the base is pulsed together with the precursor. In other embodiments, the precursor and the base are pulsed in an alternating fashion. The precursor and base can also be flowed from the same nozzle or from separate nozzles.

According to some embodiments, suitable vaporizable bases for co-flowing with the first precursor (e.g., silicon based precursor) include pyridines, amines and ammonias. In a particular embodiment, a vaporizable base, such as triethylamine, is co-flowed with the first precursor. As discussed above, the vaporizable base that is co-flowed with the first precursor is unable to react with the first precursor and chemically adsorb to the surface of the substrate. It is believed that the ALD deposition rate can be increased by co-flowing a base with the first precursor by changing surface pH of the substrate and facilitating ligand removal as the precursor covers the surface of the substrate. The addition of a base enables more precursor to adsorb on the surface of the substrate since the base can assist with ligand removal, thereby providing more reactive sites on the surface of the substrate.

With reference to FIG. 1, an embodiment of a method of increasing the deposition rate of an ALD process is described. The method 100 begins with providing a substrate in a semiconductor processing chamber in Step 110. In Step 120, a first precursor and a base in gaseous phase are pulsed into the chamber. The base is one that does not react with the first precursor such that it generates no measurable film on the substrate and no particles in the processing chamber during the flow time. In Step 130, the first precursor is allowed to chemically react with and adsorb on the surface of the substrate. In some embodiments, the first precursor is a silicon based precursor and the base can be an amine, ammonia, or pyridine. When the reaction stops after all of the reactive sites on the surface are consumed, the chamber is purged using an inert carrier gas in Step 140. Typically, N₂ or Ar can be used to purge the chamber to remove any unwanted precursor or by-products. In Step 150, a second precursor is pulsed into the chamber, and the second precursor is allowed to chemically react with and adsorb on the surface of the substrate in Step 160. In some embodiments of a plasma enhanced ALD method, the second precursor (e.g., O₂, O₃, CO₂, N₂, ammonia, etc.) is plasma ignited. After the reaction stops, once all of the reactive sites on the substrate surface are consumed, the chamber is purged again using an inert carrier gas in Step 170. In Step 180, it is determined whether the film formed on the substrate has reached the desired thickness. If the desired thickness has not been reached, Steps 110-170 are repeated again until the film formed on the substrate is at the desired thickness. When it is determined that the film on the substrate has reached the desired thickness, the ALD process is ended.

According to some embodiments for ALD of silicon dioxide (SiO2), some suitable silicon based precursors that can be pulsed as the first precursor include Bis(diethylamino)silane (BDEAS), Bis(tertiary-butylamino)silane (BTBAS), and tris(dimethylamino)silane (TDMAS). In accordance with some embodiments, a base that does not react with the silicon based precursor such that it generates a measurable film on the substrate surface or measurable particles in the chamber is co-flowed with the silicon based precursor to increase the deposition rate of the ALD process. Suitable bases for co-flowing with the first precursor include pyridines, triamines and ammonia. In a particular plasma-enhanced ALD process for SiO₂ deposition, a second precursor is plasma-ignited oxygen and is pulsed into the chamber after the chamber is purged. Other suitable precursors for oxidation in a plasma-enhanced ALD process include nitrous oxide (N₂O), carbon dioxide (CO₂), and ozone (O₃).

In accordance with another embodiment for silicon nitride (Si₃N₄) ALD, suitable silicon based precursors that can be pulsed as the first precursor include Bis(diethylamino)silane (BDEAS), Bis(tertiary-butylamino)silane (BTBAS), and tris(dimethylamino)silane (TDMAS). To increase the rate of deposition, a base that does not react with the silicon based precursor such that it generates a measurable film on the substrate surface or measurable particles in the chamber is co-flowed with the silicon based precursor. Suitable bases for co-flowing with the first precursor include pyridines, triamines and ammonia. In a particular plasma-enhanced ALD process for Si₃N₄ deposition, a second precursor is plasma-ignited nitrogen (or ammonia) and is pulsed into the chamber after the chamber is purged.

According to a non-plasma enhanced ALD process for Si₃N₄ deposition, a halide based precursor is pulsed into the chamber along with a base that does not react with the halide based precursor such that it generates a measurable film on the substrate surface or measurable particles in the chamber is co-flowed with the halide based precursor. Suitable halide based precursors include hexachlorodisilane (Si₂Cl₆) and dichlorosilane (H₂SiCl₂). In this embodiment, suitable bases for co-flowing with the halide based precursor include pyridines and triamines. According to this embodiment, the second precursor can be water or ozone.

Typically, the ALD processes described herein are carried out in a temperature range of about 50°-600° C. and at a pressure in a range of about 100 mtorr to about 10 torr. The ALD processes described herein are isobaric, where there are no pressure fluctuations. Both the dosing flow time of the precursors (and base) and the purge time are about 1-5 seconds. The precursor flow rate is in a range of about 100-1000 sccms. It will be understood that the parameters are dependent on the particular reactor used for the ALD process. The parameters given above are base on ALD processes that take place in a reactor such as the Striker® and Vector® Deposition Reactors, which is made by Lam Research Corporation of Fremont, Calif.

FIG. 2 is a flow chart of another embodiment of a method 200 of increasing the deposition rate of an ALD process. In Step 210, a semiconductor substrate is provided in a processing chamber. In Step 220, a first precursor and a base in gaseous phase are pulsed into the chamber. The base is one that does not react with the first precursor such that it generates no measurable film on the substrate and no particles in the processing chamber during the flow time. In Step 230, the first precursor is allowed to chemically react with and adsorb on the surface of the substrate. In some embodiments, the first precursor is a silicon based precursor and the base can be an amine, ammonia, or pyridine. When the reaction stops after all of the reactive sites on the surface are consumed, the chamber is purged using an inert carrier gas in Step 240. Typically, N₂ or Ar can be used to purge the chamber to remove any unwanted precursor or by-products. In Step 250, a second precursor is pulsed into the chamber along with a gaseous acid or base, and the second precursor is allowed to chemically react with and adsorb on the surface of the substrate in Step 260. In some embodiments of a plasma enhanced ALD method, the second precursor (e.g., O₂, O₃, CO₂, N₂, ammonia, etc.) is plasma ignited. After the reaction stops once all of the reactive sites on the substrate surface are consumed, the chamber is purged again using an inert carrier gas in Step 270. In Step 280, it is determined whether the film formed on the substrate has reached the desired thickness. If the desired thickness has not been reached, Steps 210-270 are repeated again until the film formed on the substrate is at the desired thickness. When it is determined that the film on the substrate has reached the desired thickness, the ALD process is ended.

Although only a few embodiments of the invention have been described in detail, it should be appreciated that the invention may be implemented in many other forms without departing from the spirit or scope of the invention. In view of all of the foregoing, it should be apparent that the present embodiments are illustrative and not restrictive and the invention is not limited to the details given herein, but may be modified within the scope and equivalents of the appended claims.

What is claimed is:

1. A method for increasing a deposition rate of an atomic layer deposition (ALD) process, the method comprising:
providing a processing chamber, wherein a substrate is within the chamber;
flowing a first precursor into the chamber, the first precursor comprising a metal organic, a metal halide, or metal hybride, wherein adsorption of the first precursor results in a growth of a film on the substrate;
co-flowing a base in a gaseous phase with the first precursor into the chamber to co-expose a surface of the substrate to the first precursor and the base, wherein the base does not generate any measurable film on the surface of the substrate and the base does not generate any measurable particles in the chamber; and
flowing a second precursor into the chamber, wherein adsorption of the second precursor provides oxidation or nitridation of the film.

2. The method as recited in claim 1, further comprising purging the processing chamber after co-flowing the base and before flowing the second precursor.

3. The method as recited in claim 1, wherein the base is selected from the group consisting of pyridines, amines and ammonias.

4. The method as recited in claim 1, wherein co-flowing the base comprises pulsing the base and the first precursor together.

5. The method as recited in claim 1, wherein co-flowing the base comprises alternating pulses of the first precursor with pulses of the base.

6. The method as recited in claim 1, further comprising co-flowing a base with the second precursor.

7. The method as recited in claim 1, further comprising co-flowing an acid with the second precursor.

8. The method as recited in claim 7, wherein the ALD process is not a plasma-enhanced process.

9. The method as recited in claim 2, further comprising purging the processing chamber after flowing the second precursor.

10. A method for increasing a deposition rate of an atomic layer deposition (ALD) process, the method comprising:
providing a processing chamber, wherein a substrate is within the chamber;
flowing a first precursor into the chamber, wherein the first precursor is a metal organic, a metal halide, or metal hybride and wherein adsorption of the first precursor results in a growth of a film on the substrate;
co-flowing a volatile base with the first precursor into the chamber to co-expose a surface of the substrate to the first precursor and the base, wherein the base does not generate any measurable film on the surface of the substrate and the base does not generate any measurable particles in the chamber; and
co-flowing a volatile base or acid with a second precursor into the chamber, wherein adsorption of the second precursor provides oxidation or nitridation of the film.

11. The method as recited in claim 10, wherein the base is selected from the group consisting of pyridines, amines and ammonias.

12. The method as recited in claim 10, wherein co-flowing the base comprises pulsing the base and the first precursor together.

13. The method as recited in claim 10, wherein co-flowing the base comprises alternating pulses of the first precursor with pulses of the base.

14. A method for increasing a deposition rate of a plasma-enhanced atomic layer deposition (ALD) process, the method comprising:
providing a processing chamber, wherein a substrate is within the chamber;
flowing a first precursor into the chamber, the first precursor comprising metal organic, a metal halide, or metal hybride, wherein adsorption of the first precursor results in a growth of a film on the substrate;
co-flowing a base in a gaseous phase with the first precursor into the chamber to co-expose a surface of the substrate to the first precursor and the base, wherein the base does not generate any measurable film on the surface of the substrate and the base does not generate any measurable particles in the chamber; and
flowing a second precursor into the chamber, wherein the second precursor is plasma ignited and adsorption of the second precursor provides oxidation or nitridation of the film.

15. The method as recited in claim 14, wherein the first precursor is selected from the group consisting of Bis(diethylamino)silane (BDEAS), Bis(tertiary-butylamino)silane (BTBAS), and tris(dimethylamino)silane (TDMAS).

16. The method as recited in claim 14, wherein the base is selected from the group consisting of pyridine, triamine, and ammonia.

17. The method as recited in claim 14, wherein the second precursor is selected from the group consisting of oxygen, nitrous oxide, carbon dioxide, ozone, nitrogen, and ammonia.

18. The method as recited in claim 14, wherein co-flowing the base comprises pulsing the base and the first precursor together.

19. The method as recited in claim 14, wherein co-flowing the base comprises alternating pulses of the first precursor with pulses of the base.

20. The method as recited in claim 14, wherein the base comprises triethylamine.
